(19) United States
(12) Patent Application Publication
(10) Pub. No.: US 2008/0142892 A1
(43) Pub. Date: Jun. 19, 2008

(54) INTERCONNECT FEATURE HAVING ONE OR MORE OPENINGS THEREIN AND METHOD OF MANUFACTURE THEREFOR

(75) Inventor: Mikel R. Miller, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/611,409

(22) Filed: Dec. 15, 2006

(51) Int. Cl. H01L 29/78; H01L 23/52; H01L 21/4763

(52) U.S. Cl. 257/368; 257/774; 438/618; 257/E29.255; 257/E21.495; 257/E23.141

(57) ABSTRACT

Provided is a metallization system, a method for manufacture therefore, and a semiconductor device. The metallization system, in one embodiment, comprises a dielectric layer, as well as an interconnect feature located over the dielectric layer. The interconnect feature, in this embodiment, includes one or more openings extending therethrough, the one ore more openings having a radius of curvature of greater than about 150 nm.

### TECHNICAL FIELD

This disclosure is directed, in general, to a metallization system and, more specifically, to a metallization system including an interconnect feature having one or more openings therein and a method of manufacture therefore.

### BACKGROUND

Individual semiconductor devices in integrated circuits are typically interconnected by means of one or more electrically conductive features comprising a high conductivity metal or metal alloy. These conductive features generally include both interconnect traces and interconnect vias. As integrated circuits have continued to shrink in size and increase in complexity, the spacing of the interconnect traces has also decreased.

These interconnect traces, however, have begun to experience reliability issues. For example, in sub-half micron interconnect systems, reliability-limiting wear out mechanisms include electromigration and stress-induced voiding. Both of these mechanisms, when significant enough, are capable of causing complete failure of the integrated circuit.

Accordingly, what is needed in the art is an interconnect system that does not experience the drawbacks experienced by the prior art systems.

### SUMMARY

To address the above-discussed deficiencies of the prior art, in the embodiments discussed herein, there is provided a metallization system for use with a semiconductor device, a method for manufacture therefore, and a semiconductor device. The metallization system, in one embodiment, comprises a dielectric layer, as well as a conductive feature located over the dielectric layer. The conductive feature, in this embodiment, includes one or more openings extending therethrough, the one or more openings having a radius of curvature of greater than about 150 nm.

The metallization system, in another embodiment, also includes a dielectric layer, and a conductive feature located over the dielectric layer and having one or more openings extending therethrough. In this embodiment, however, the one or more openings have a short edge and a long edge, wherein the short edge comprises two or more segments, and at least one of the segments meets the long edge at an angle greater than 90 degrees.

The method for manufacturing the metallization system, among other steps, includes forming a conductive layer over a dielectric layer, and patterning the conductive layer into an interconnect feature, the interconnect feature having one or more openings extending therethrough. In this embodiment, the one or more openings have a radius of curvature of greater than about 150 nm.

In another embodiment, a semiconductor device is provided. The semiconductor device includes: 1) gate structures located over a substrate, 2) source/drain regions located proximate each of the gate structures, the source/drain regions located in, on or over the substrate, 3) a dielectric layer located over the gate structures, and 4) an interconnect feature located over the dielectric layer, wherein the interconnect feature has one or more openings extending therethrough, the one ore more openings having a radius of curvature of greater than about 150 nm.

### BRIEF DESCRIPTION OF THE DRAWINGS

For a more complete understanding of the following discussion, reference is now made to the descriptions taken in conjunction with the accompanying drawings, in which:

FIGS. 1A-1B illustrate a metallization system manufactured in accordance with the invention;

FIGS. 2A-2C illustrate an alternative embodiment of a manufactured metallization system;

FIGS. 3A-3B illustrate an alternative embodiment of a manufactured metallization system;

FIG. 4 illustrates another alternative embodiment of a manufactured metallization system; and

FIG. 5 illustrates a semiconductor device (e.g., an integrated circuit (IC)) incorporating an embodiment of a metallization system described herein.

### DETAILED DESCRIPTION

It is presently recognized that sharp corners in openings included within interconnect feature cause localized stress concentrations and current crowding. It is further realized that the localized stress concentrations and current crowding can lead to decreased reliability and reduced current carrying capability.

Based upon these realizations, and a substantial amount of experimentation, it has been found that by using non-sharp corners, the localized stress concentrations and current crowding are reduced. It is believed that the non-sharp corners more equally distribute the stress and current around the opening. The reduced localized stress concentration would in turn reduce the tendency for nearby metal and dielectric layers to crack. Additionally, the reduced localized current crowding would reduce electromigration, which is a key failure mode in conductive lines.

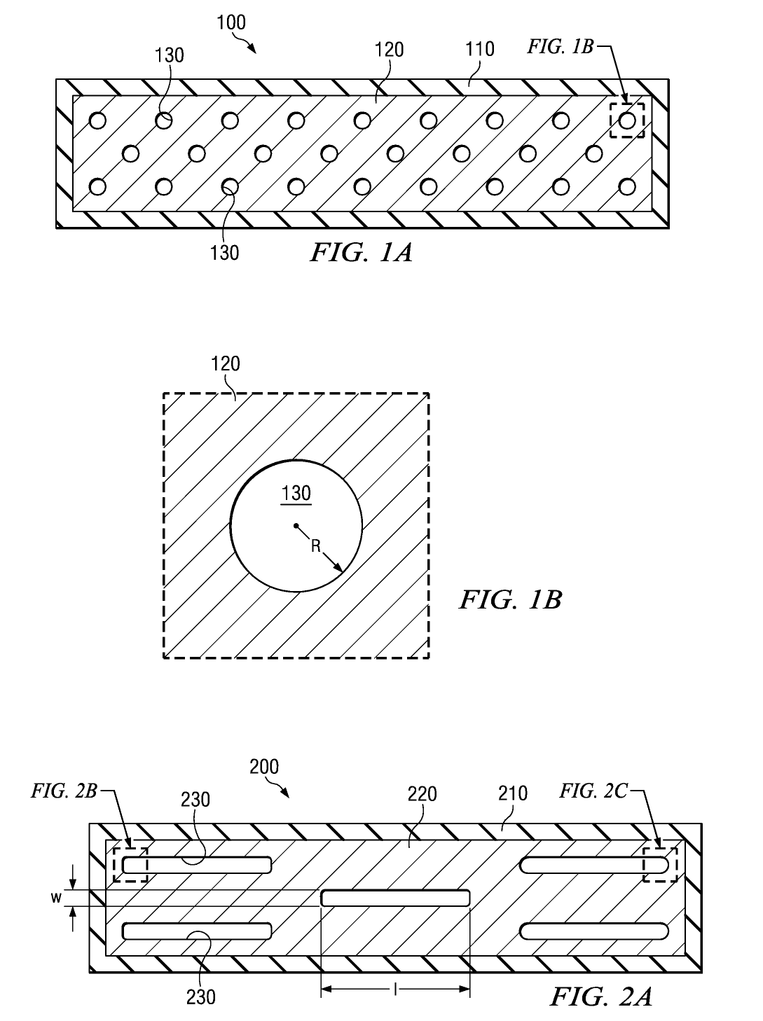

FIGS. 1A thru 1B illustrate one embodiment of a metallization system 100, as might be used with a semiconductor device. The metallization system 100 of FIGS. 1A thru 1B includes a dielectric layer 110. The dielectric layer 110 may be any known or hereafter discovered dielectric material. For instance, the dielectric layer 110 may comprise silicon dioxide, a low dielectric constant material, etc.

Located over the dielectric layer 110 is a interconnect feature 120. The term interconnect feature, as used throughout this disclosure, refers to a conductive feature used to interconnect various features of a semiconductor device. The term interconnect feature, however, does not refer to printed wire boards or other millimeter or larger scale features. The interconnect feature 120 in the embodiment of FIG. 1A is a metal conductive trace located below a passivation layer in a semiconductor device. For instance, the interconnect feature 120 could comprise an aluminum conductive trace, among others. Other embodiments exist wherein the interconnect feature 120 comprises other metals, or non-metallic conductive materials.

The interconnect feature 120 of FIG. 1A includes one or more openings 130 extending therethrough. The openings 130 have a radius of curvature (R) of greater than about 150 nm. The openings 130 in FIGS. 1A thru 1B are illustrated as circles that extend through the interconnect feature 120. Accordingly, in the embodiment of FIGS. 1A thru 1B the radius of curvature (R) is the radius of the circle. Nevertheless, other embodiments exist wherein the openings 130 comprise different shapes.

The size, number and location of the openings 130 in the interconnect feature 120 will depend on a number of factors. For example, the size and number of openings 130 in the interconnect feature 120 will depend on the amount of stress that needs to be dealt with. The greater the total cross-sectional area of the openings 130, the more stress that can be dealt with. Obviously, the greater the total cross-sectional area of the openings 130, the less total cross-sectional area of the interconnect feature 120, which could lead to current crowding. Thus, the total cross-sectional area of the openings 130 should be adjusted (e.g., tailored) to accommodate both the desire for stress reduction, as well as the need for current flow.

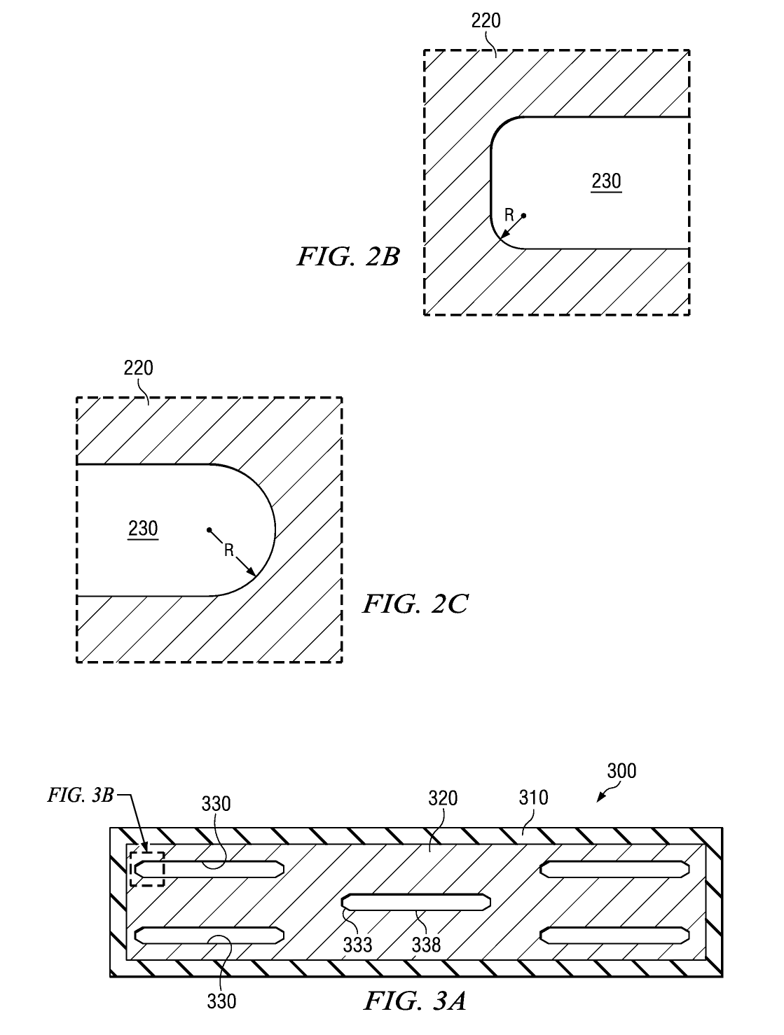

FIGS. 2A thru 2C illustrate an alternative embodiment of a metallization system 200. The metallization system 200 includes a dielectric layer 210. The dielectric layer 210 may comprise similar materials as the dielectric layer 110. Located over the dielectric layer 210 is a interconnect feature 220. The interconnect feature 220 may comprise similar materials as the interconnect feature 120.

The interconnect feature 220 of FIG. 2A includes one or more openings 230. The openings 230 in the embodiment of FIGS. 2A thru 2C comprise slots extending through the interconnect feature 220. The slots, in this embodiment, have a length value (1) and a width value (w). Moreover, the slots have a radius of curvature (R) greater than about 150 nm, and in an alternative embodiment greater than about 750 nm. In another embodiment, the slots have a radius of curvature (R) of greater than about 10 percent of the width value (w). In those embodiments wherein the slots have a radius of curvature (R) up to, but not including, 50 percent of the width value (w), the slots will generally have four radius of curvature (R) values. FIG. 2B illustrates one such embodiment. If the slots have a radius of curvature (R) of 50 percent of the width value (w), then the slots will generally have only two radius of curvature (R) values. FIG. 2C illustrates one such embodiment.

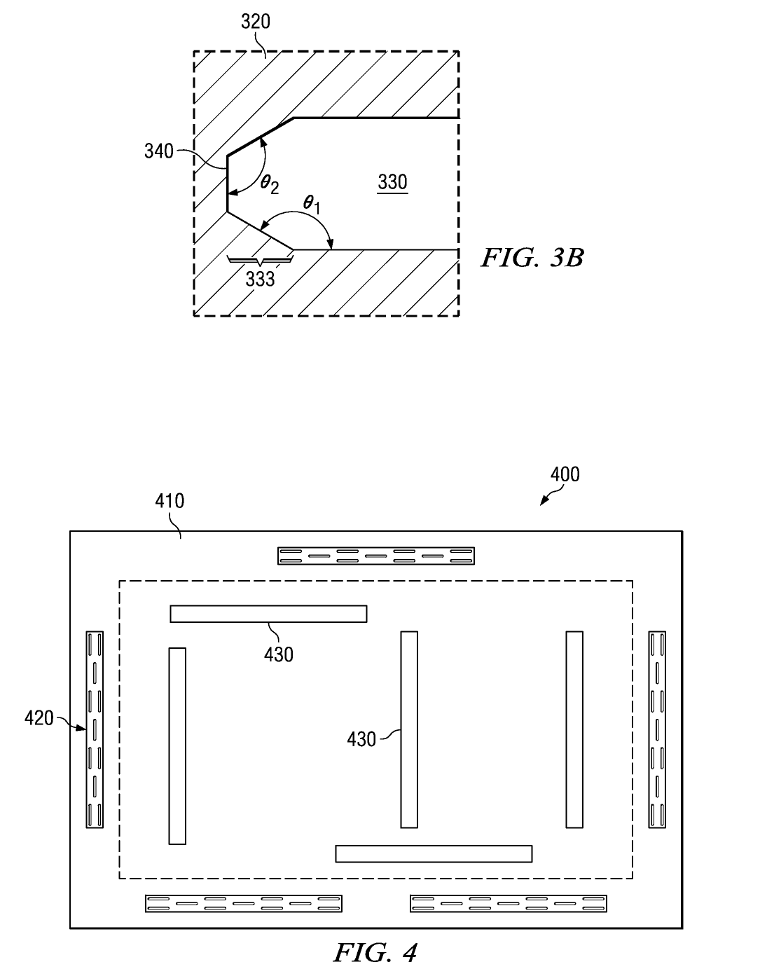

FIGS. 3A thru 3B illustrate an alternative embodiment of a metallization system 300. The metallization system 300 includes a dielectric layer 310. The dielectric layer 310 may comprise similar materials as the dielectric layers 110, 210. Located over the dielectric layer 310 is a interconnect feature 320. The interconnect feature 320 may comprise similar materials as the interconnect features 120, 220.

The interconnect feature 320 of FIG. 3A includes one or more openings 330. The openings 330 in the embodiment of FIGS. 3A thru 3B comprise slots extending through the interconnect feature 320. The slots, in this embodiment, comprise two short edges 333 and two long edges 338, wherein the short edges 333 each comprise two or more segments 340. At least one of the segments 340 of the short edges 333 meets a long edge 338 at an angle (θ₁) greater than 90 degrees. In many instance, the angle (θ₁) will range from about 115 degrees to about 155 degrees. Because of the increased angle (θ₁), as opposed to the short edges 333 and long edges 338 meeting one another at perpendicular angles, the localized stress concentration and current crowding should be reduced.

In many embodiments, the segments 340 meet one another at an angle (θ₂) that is also greater than 90 degrees. For example, the angle (θ₂) may range from about 115 degrees to about 155 degrees, among others. This value, however, will depend on the number of segments 340 each short edge 333 comprises. It is believed that the more segments 340 each short edge 333 comprises, the less likely the system 300 is to experience localized stress and current crowding.

FIG. 4 illustrates an alternative embodiment of a metallization system 400. The metallization system 400 includes a dielectric layer 410. The dielectric layer 410 may comprise similar materials as the previously described dielectric layers 110, 210, 310. The dielectric layer 410, in the embodiment shown, includes a footprint.

The metallization system 400 of FIG. 4 includes one or more first interconnect features 420, wherein the first interconnect features 420 have openings (e.g., as discussed in previous embodiments) therethrough. The metallization system 400 of FIG. 4 further includes one or more second interconnect features 430, wherein the second interconnect features 430 do not contain openings therethrough. Accordingly, the metallization system 400 may include some interconnect features that include openings constructed in accordance with the invention as well as some interconnect features that do not include openings constructed in accordance with the invention. In the illustrated embodiment, the first interconnect features 420 are located in an outer 20 percent of the footprint, wherein the second interconnect features 430 are located inside an inner 80 percent of the footprint.

Those skilled in the art understand the process for forming the interconnect features disclosed herein. For example, in one embodiment a conductive layer may be patterned into one or more conductive features. This patterning step may, or may not, form the one or more openings within the conductive features. If this patterning step does not form the one or more openings within the conductive features, additional patterning steps may be required to form those openings.

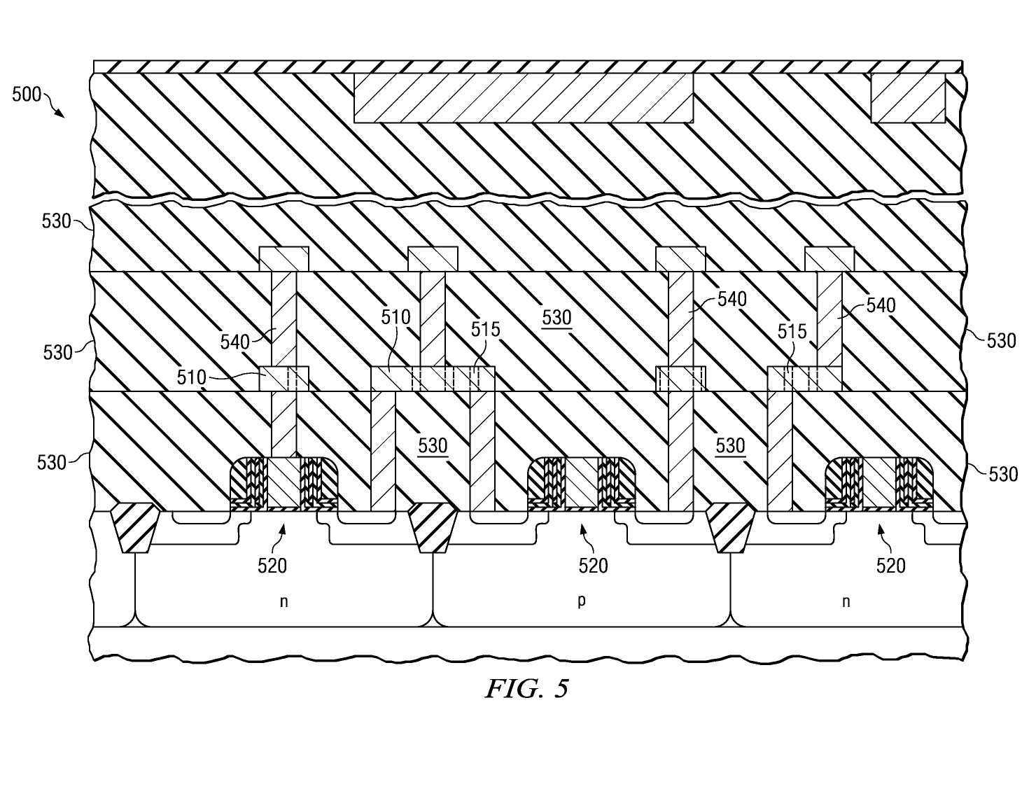

FIG. 5 illustrates a semiconductor device 500 (e.g., an integrated circuit (IC)) in to which a metallization system 510 having openings 515, such as described in the embodiments above, may be incorporated. The semiconductor device 500 may include devices, such as transistors used to form CMOS devices, BiCMOS devices, bipolar devices, or other types of devices. The semiconductor device 500 may further include passive devices, such as inductors or resistors, or it may also include optical devices or optoelectronic devices. Those skilled in the art are familiar with these various types of devices and their manufacture. In the particular embodiment illustrated in FIG. 5, the semiconductor device 500 includes transistor devices 520 (e.g., including gate structures, source/drain regions, etc.) having the metallization system 510 located thereover. The metallization system 510, as well as additional dielectric and conductive features, contact the transistor devices 520, thus, forming the operational semiconductor device 500.

Those skilled in the art to which the invention relates will appreciate that other and further additions, deletions, substitutions and modifications may be made to the described embodiments without departing from the scope of the invention.

What is claimed is:

1. A metallization system for use with a semiconductor device, comprising:
a dielectric layer; and
an interconnect feature located over the dielectric layer, wherein the interconnect feature has one or more openings extending therethrough, the one ore more openings having a radius of curvature of greater than about 150 nm.

2. The metallization system as recited in claim 1 wherein the radius of curvature is greater than about 750 nm.

3. The metallization system as recited in claim 1 wherein the one or more openings are one or more slots having a length value and a width value, the one or more slots having a radius of curvature greater than about 10 percent of the width value.

4. The metallization system as recited in claim 3 wherein the one or more slots have four radius of curvature greater than about 10 percent of the width value.

5. The metallization system as recited in claim 3 wherein the one or more slots have two radius of curvature equal to 50 percent of the width value.

6. The metallization system as recited in claim 1 wherein the one or more openings are one or more circles extending through the interconnect feature.

7. The metallization system as recited in claim 1 wherein the dielectric layer has a footprint, and further wherein the interconnect feature is located in an outer 20 percent of the footprint.

8. The metallization system as recited in claim 7 wherein the interconnect feature is a first interconnect feature, and further including a second interconnect feature located over the dielectric layer, the second interconnect feature without the one or more openings extending therethrough and located inside an inner 80 percent of the footprint.

9. A method for manufacturing a metallization system for use with a semiconductor device, comprising:
forming a conductive layer over a dielectric layer; and
patterning the conductive layer into an interconnect feature, the interconnect feature having one or more openings extending therethrough, the one ore more openings having a radius of curvature of greater than about 150 nm.

10. The method as recited in claim 9 wherein the one or more openings are one or more slots having a length value and a width value, the one or more slots having a radius of curvature greater than about 10 percent of the width value.

11. The method as recited in claim 10 wherein the one or more slots have two radius of curvature equal to 50 percent of the width value.

12. The method as recited in claim 9 wherein the one or more openings are one or more circles extending through the interconnect feature.

13. A semiconductor device, comprising:
gate structures located over a semiconductor substrate;
source/drain regions located proximate each of the gate structures, the source/drain regions located in, on or over the semiconductor substrate;
a dielectric layer located over the gate structures;
an interconnect feature located over the dielectric layer, wherein the interconnect feature has one or more openings extending therethrough, the one ore more openings having a radius of curvature of greater than about 150 nm.

14. The semiconductor device as recited in claim 13 wherein the radius of curvature is greater than about 750 nm.

15. The semiconductor device as recited in claim 13 wherein the one or more openings are one or more slots having a length value and a width value, the one or more slots having a radius of curvature greater than about 10 percent of the width value.

16. The semiconductor device as recited in claim 15 wherein the one or more slots have two radius of curvature equal to 50 percent of the width value.

17. The semiconductor device as recited in claim 13 wherein the one or more openings are one or more circles extending through the interconnect feature.

18. The semiconductor device as recited in claim 13 wherein the dielectric layer has a footprint, and further wherein the interconnect feature is located in an outer 20 percent of the footprint.

19. The semiconductor device as recited in claim 18 wherein the interconnect feature is a first interconnect feature, and further including a second interconnect feature located over the dielectric layer, the second interconnect feature without the one or more openings extending therethrough and located inside an inner 80 percent of the footprint.

20. A metallization system for use with a semiconductor device, comprising:
a dielectric layer; and
an interconnect feature located over the dielectric layer, the interconnect feature having one or more openings extending therethrough, the one or more openings having a short edge and a long edge, wherein the short edge comprises two or more segments, and at least one of the segments meets the long edge at an angle greater than 90 degrees.
